(19) United States
(12) Patent Application Publication
(10) Pub. No.: US 2025/0149380 A1
(43) Pub. Date: May 8, 2025

(54) INTERCONNECT STRUCTURE AND METHOD OF FORMING SAME

(71) Applicant: Taiwan Semiconductor Manufacturing Co., Ltd., Hsinchu (TW)

(72) Inventors: Ming-Da Cheng, Taoyuan City (TW); Eugene Chow Chi Hao, Tainan City (TW); Chang-Jung Hsueh, Taipei (TW); Chun-Fu Wu, Hsinchu County (TW); Wen-Hsiung Lu, Tainan City (TW)

(21) Appl. No.: 18/415,770

(22) Filed: Jan. 18, 2024

Related U.S. Application Data
(60) Provisional application No. 63/595,652, filed on Nov. 2, 2023.

(51) Int. Cl. H01L 21/768; C23C 18/38; H01L 21/285; H01L 21/288

(52) U.S. Cl. CPC H01L 21/76877; C23C 18/38; H01L 21/28512; H01L 21/2885

(57) ABSTRACT

A method includes adding a first additive to an electroplating solution, wherein the first additive is a relatively weak suppressing agent; adding a second additive to the electroplating solution, wherein the second additive is a relatively strong suppressing agent; adding a third additive to the electroplating solution, wherein the third additive is a leveling agent; and depositing copper using the electroplating solution, wherein most of the copper is nanotwinned grains having a (111)-orientation.

### PRIORITY CLAIM AND CROSS-REFERENCE

This application claims the benefit of U.S. Provisional Application No. 63/595,652, filed on Nov. 2, 2023, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of an integrated circuit die, in accordance with some embodiments.

FIGS. 2, 3, 4, 5, 6, 7, 8, and 9 illustrate cross-sectional views of intermediate steps during a process for forming a conductive feature, in accordance with some embodiments.

FIG. 10 illustrates a cross-sectional view of a conductive feature, in accordance with some embodiments.

FIG. 11 illustrates a cross-sectional view of a conductive feature, in accordance with some embodiments.

FIGS. 12, 13, 14, and 15 illustrate cross-sectional views of intermediate steps during a process for forming a conductive feature, in accordance with some embodiments.

FIG. 16 illustrates a cross-sectional view of an interconnect structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a process for forming a conductive feature includes the use of additives in a copper electroplating process. The additives include a weak suppressor additive that includes a suppressing functional group and a metal-coordinating functional group, a strong suppressor additive, and a leveler additive. The use of these additives during the electroplating process promote the growth of nanotwinned copper, such as (111)-oriented copper. In this manner, a conductive feature may be formed largely of (111)-oriented copper. Additionally, the additives can form conductive features having low surface roughness.

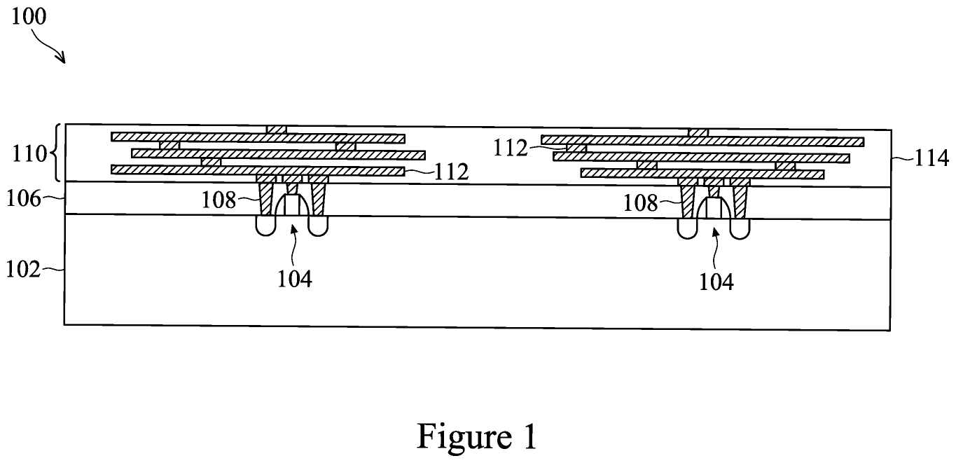

FIG. 1 illustrates a cross-sectional view of an intermediate stage in the manufacturing of an integrated circuit die 100, in accordance with some embodiments. FIG. 1 may illustrate, for example, a device region within which the integrated circuit die 100 is formed. The integrated circuit die 100 may be a logic device (e.g., central processing unit (CPU), graphics processing unit (GPU), microcontroller, etc.), a memory device (e.g., dynamic random access memory (DRAM) die, static random access memory (SRAM) die, etc.), a power management device (e.g., power management integrated circuit (PMIC) die), a radio frequency (RF) device, a sensor device, a micro-electro-mechanical-system (MEMS) device, a signal processing device (e.g., digital signal processing (DSP) die), a front-end device (e.g., analog front-end (AFE) dies), the like, or combinations thereof (e.g., a system-on-a-chip (SoC) die). The integrated circuit die 100 may be formed in a wafer or the like, which may include a plurality of device regions. The device regions may be subsequently singulated to form individual integrated circuit dies 100, in some cases. The integrated circuit die 100 is used as an illustrative example, and the embodiments or techniques described herein may be applied to other structures such as interposers, packages, interconnects, chips, chiplets, or the like, which may or may not include active devices.

The integrated circuit die 100 may be processed according to applicable manufacturing processes to form integrated circuits. For example, the integrated circuit die 100 may include a substrate 102, which may be a semiconductor substrate such as silicon, doped or undoped, or an active layer of a semiconductor-on-insulator (SOI) substrate. The substrate 102 may include other semiconductor materials, such as germanium; a compound semiconductor including silicon carbide, gallium arsenic, gallium phosphide, indium phosphide, indium arsenide, and/or indium antimonide; an alloy semiconductor including silicon germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. In some embodiments, the substrate 102 may be a wafer, such as a silicon wafer or the like. In some embodiments, the substrate 102 has an active surface (e.g., the surface facing upwards in FIG. 1), sometimes called a front side, and an inactive surface (e.g., the surface facing downwards in FIG. 1), sometimes called a back side.

Devices 104 (represented in FIG. 1 by transistors) may be formed at the active surface of the substrate 102. The devices 104 may be formed in a front-end of line (FEOL) process using applicable manufacturing processes, such as acceptable deposition, photolithography, and etching techniques. The devices 104 may include active devices (e.g., transistors, diodes, etc.), capacitors, resistors, or the like. For example, the devices 104 may include gate structures and source/drain regions, where the gate structures are on channel regions, and the source/drain regions are adjacent the channel regions. Source/drain region(s) may refer to a source or a drain, individually or collectively dependent upon the context. The channel regions may be patterned regions of the substrate 102. For example, the channel regions may be regions of semiconductor fins, semiconductor nanostructures, semiconductor nanosheets, semiconductor nanowires, or the like that are formed in or on the substrate 102. When the devices 104 are transistors, they may be any suitable type of transistors, such as nanostructure field-effect transistors (nanostructure-FETs), fin field-effect transistors (FinFETs), planar transistors, or the like. Other devices 104 are possible.

In some embodiments, an inter-layer dielectric (ILD) 106 is formed over the active surface of the substrate 102. The ILD 106 surrounds and may cover the devices 104. The ILD 106 may include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like, which may be formed by a deposition process such as spin coating, lamination, chemical vapor deposition (CVD), flowable CVD, or the like. Contacts 108 may be formed that extend through the ILD 106 to electrically and physically couple the devices 104. For example, when the devices 104 are transistors, the contacts 108 may couple the gates and/or the source/drain regions of the transistors. The contacts 108 may be formed of suitable conductive materials such as tungsten, cobalt, ruthenium, nickel, copper, silver, gold, aluminum, the like, or combinations thereof, which may be formed by a deposition process such as physical vapor deposition (PVD) or CVD, a plating process such as electrolytic plating or electroless plating, or the like.

In some embodiments, an interconnect structure 110 is formed over the ILD 106 and contacts 108. The interconnect structure 110 may be electrically connected to the devices 104 by the contacts 108. In this manner, the interconnect structure 110 provides interconnections and electrical routing for the integrated circuit die 100. In some cases, the interconnect structure 110 may be formed in a back-end of line (BEOL) process. In some cases, more than one interconnect structure may be formed, each of which may comprise different materials or have other different characteristics.

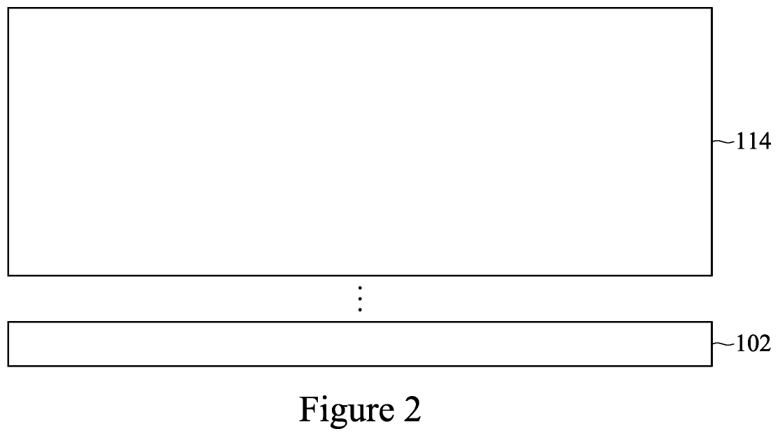

The interconnect structure 110 may be formed of, for example, a plurality of conductive features 112 formed in a plurality of dielectric layers 114. The various dielectric layers 114 are not individually illustrated in FIG. 1. The conductive features 112 may comprise, for example, conductive lines, conductive vias, conductive pads, metallization patterns, redistribution layers, or the like. The conductive features 112 include metal lines and vias, which may be formed in the dielectric layers 114 by a deposition process, a damascene process (e.g., a single damascene process, a dual damascene process, or the like), or the like. The conductive features 112 may be formed of a suitable conductive material, such as copper, tungsten, aluminum, silver, gold, a combination thereof, or the like. FIGS. 2 through 9, described in greater detail below, illustrate intermediate steps in the formation of a conductive feature 112 comprising copper, in accordance with some embodiments.

In some embodiments, the dielectric layers 114 may be formed of a polymer, such as polybenzoxazole (PBO), polyimide, benzocyclobutene (BCB), or the like; a nitride such as silicon nitride; an oxide such as silicon oxide, silicon oxynitride, phosphosilicate glass (PSG), borosilicate glass (BSG), boron-doped phosphosilicate glass (BPSG), a tetraethyl orthosilicate (TEOS) based oxide, a flowable CVD (FCVD) oxide, or the like; a molding material, encapsulant, epoxy, or the like; or the like; or a combination thereof. The dielectric layers 114 may be, e.g., low-k dielectric layers. The dielectric layers 114 may be formed by any acceptable deposition process, such as spin coating, CVD, lamination, the like, or a combination thereof. In some cases, the dielectric layers 114 may include etch stop layers (not individually illustrated). The dielectric layers 114 may be the same material or may comprise different materials.

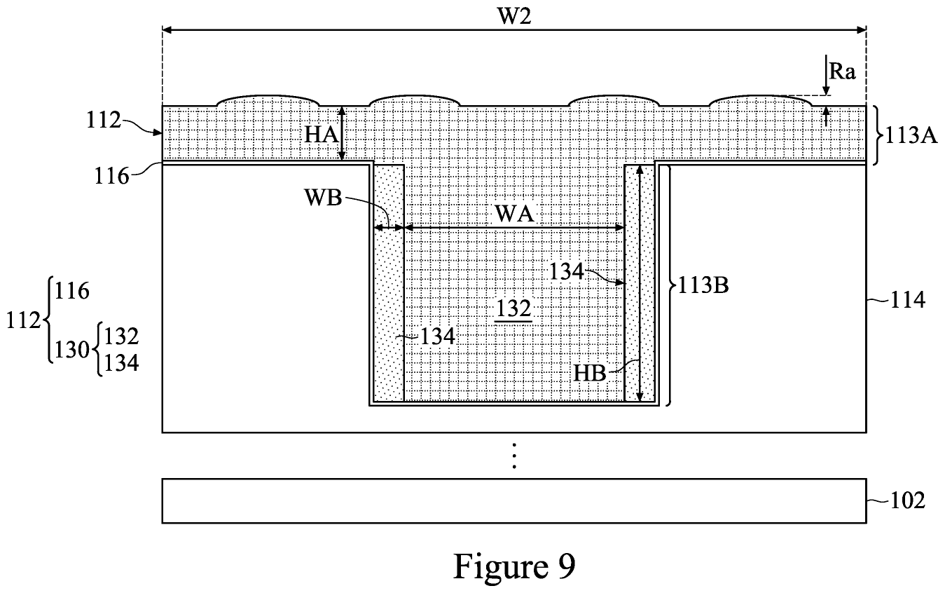

FIGS. 2 through 9 illustrate intermediate steps in the formation of a conductive feature 112 (see FIG. 9), in accordance with some embodiments. The conductive feature 112 may be similar to those described previously for FIG. 1. For example, the conductive feature 112 may be formed in a dielectric layer 114. In this manner, the steps shown in FIGS. 2-9 may be intermediate steps in the formation of an interconnect structure 110. As an illustrative example, the conductive feature 112 comprises an upper portion 113A (e.g., a conductive line portion) and a lower portion 113B (e.g., a conductive via portion), but other conductive features 112 may be formed using the materials and techniques described herein.

FIG. 2 illustrates a cross-sectional view of a dielectric layer 114 over a substrate 102, in accordance with some embodiments. The dielectric layer 114 may be one of the dielectric layers 114 of the interconnect structure 110 of FIG. 1, for example. Accordingly, the dielectric layer 114 may be similar to the dielectric layers 114 described previously for FIG. 1, though other dielectric layers are possible.

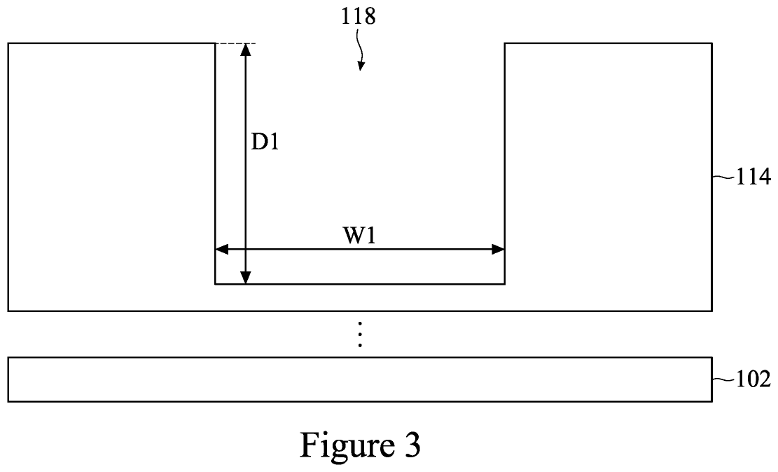

In FIG. 3, an opening 118 is formed in the dielectric layer 114, in accordance with some embodiments. FIG. 3 illustrates the opening 118 extending partially through the dielectric layer 114, but in other embodiments the opening 118 may extend fully through the dielectric layer 114, and may extend into an underlying dielectric layer. In other embodiments, the opening 118 may expose an underlying conductive feature or may expose an underlying dielectric layer. In some embodiments, the opening 118 may “stop” on an etch stop layer (not illustrated), and may expose that etch stop layer. In some embodiments, the opening 118 may be formed having a depth D1 from a top surface of the dielectric layer 114 that is in the range of about 0.5 μm to about 200 μm, though other depths are possible. In some embodiments, the openings 118 may be formed having a width W1 in the range of about 0.2 μm to about 60 μm, though other widths are possible. FIG. 3 illustrates the opening 118 as having approximately vertical sidewalls, but in other embodiments, the opening 118 may have oblique sidewalls, tapered sidewalls, convex sidewalls, concave sidewalls, or sidewalls having another profile than these examples.

The opening 118 may be formed using suitable photolithography and etching techniques. For example, in some embodiments, a photoresist (not illustrated) is formed over the dielectric layer 114 and patterned. The photoresist may be deposited using a suitable technique such as spin coating or the like. The photoresist may then be exposed to light for patterning, for which the pattern of the photoresist corresponds to the opening 118. The photoresist may then be patterned using suitable developing techniques. The opening 118 may then be formed by performing one or more etching steps, using the patterned photoresist as an etching mask. The etching steps may include one or more suitable wet etching processes and/or dry etching processes.

In other embodiments for which the dielectric layer 114 is formed of a photo-sensitive material such as PBO, polyimide, BCB, or the like, the dielectric layer may be patterned using a lithography mask. The patterning may include a suitable process, such as exposing and developing the dielectric layer 114 to light. The dielectric layer 114 may then be developed to form the opening 118.

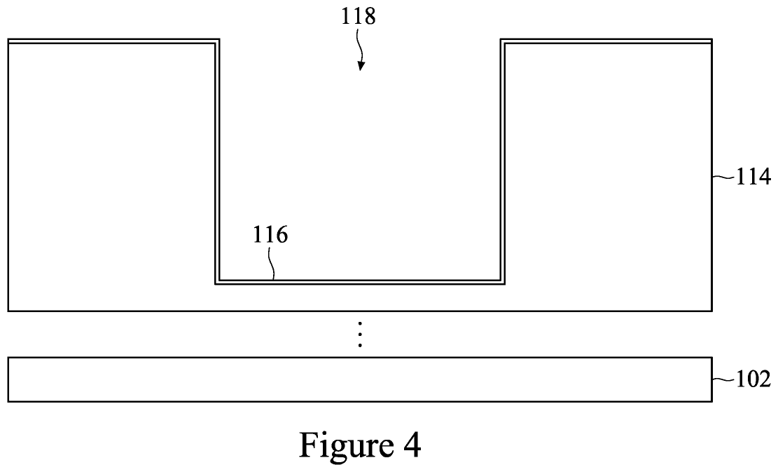

In FIG. 4 a seed layer 116 is deposited on surfaces of the dielectric layer 114 and within the opening 118, in accordance with some embodiments. The seed layer 116 is a metal layer, which may be a single layer or a composite layer comprising a plurality layers formed of different materials. In some embodiments, the seed layer 116 comprises a titanium layer and a copper layer over the titanium layer, though other materials or combinations thereof are possible. The seed layer 116 may be conformally deposited using, for example, physical vapor deposition (PVD) or the like. In some embodiments, the seed layer 116 also comprises one or more liner layers, such as a barrier layer, an adhesion layer, a glue layer, or the like.

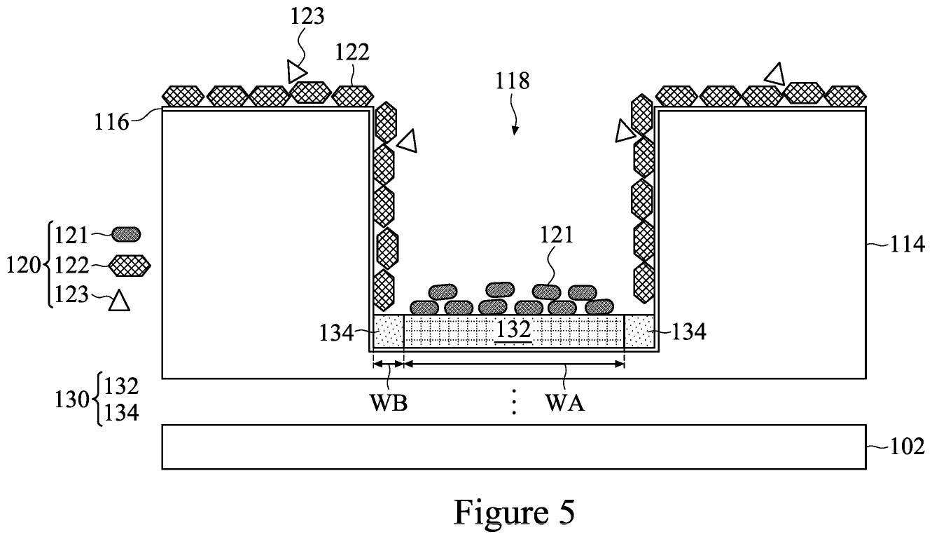

FIGS. 5 through 9 illustrate intermediate stages in the deposition of a conductive material to form a conductive feature 112, in accordance with some embodiments. In FIGS. 5-9, the conductive material is copper deposited using an electroplating process. In some embodiments, the electroplating process comprises the use of additives 120 (e.g., additives 121, 122, and 123, described below) that promote the bottom-up deposition of copper having a (111)-oriented crystalline structure. In this manner, the conductive feature 112 may be formed mostly of (111)-oriented copper, which can provide benefits of (111)-oriented copper, such as good mechanical properties (e.g., good tensile strength), good conductive properties, or good thermal stability. In some embodiments, the copper is deposited as a polycrystalline structure comprising a plurality of grains that are largely (111)-oriented. In some cases, a copper layer having a uniform grain orientation may be referred to as nanotwinned copper (nt-Cu), such as (111)-oriented nt-Cu. In some cases, the techniques described herein allow for the formation of a copper layer that is at least about 97% (111)-oriented copper, though other amounts of (111)-oriented copper are possible. For example, a scanning electron microscope (SEM) analysis or an electron backscatter diffraction (EBSD) analysis of a copper layer formed using the techniques described herein may show that greater than 97% of the copper is (111)-oriented. In some cases, the techniques described herein allow for extreme bottom-up filling with good topography control and low surface roughness.

The electroplating process comprises submerging the structure (including the seed layer 116) in an electroplating solution, and applying a potential to generate an electric current within the electroplating solution. In some embodiments, the electroplating process is performed at a temperature in the range of about 10° C. to about 50° C. In some embodiments, the current density of the electroplating process is in the range of about 0.1 ASD to about 10 ASD. In some embodiments, the electroplating process is performed for a duration of time in the range of about 30 seconds to about 15 minutes. Other electroplating process parameters or conditions are possible. In some embodiments, the amount of deposited copper may be controlled by controlling the electric current and/or the duration of time of the electroplating process.

In some embodiments, the electroplating solution comprises a copper salt, a source of halide ions, an acid, and one or more additives (e.g. additives 121, 122, and/or 123). The copper salt provides copper ions (e.g., Cu²⁺) to the electroplating solution, and may include one or more suitable copper salts such as supper (II) sulfate copper acetate, copper gluconate, copper fluoroborate, cupric nitrate, copper alkanesulfonates, copper arylsulfonates, the like, or a combination thereof. Other copper salts or functionally similar materials may be used in other embodiments. In some embodiments, the copper salt is present in an amount sufficient to provide an amount of copper ions in the range of about 10 g/L to about 50 g/L in the electroplating solution. In some embodiments, the source of halide ions may be hydrochloric acid (e.g., which provides chloride ions) or the like. In some embodiments, the acid may comprise sulfuric acid, nitric acid, methanesulfonic acid, phenylsulfonic acid, the like, or a combination thereof. Other copper salts, sources of halide ions, acids, or combinations thereof may be used in other embodiments.

In some embodiments, the electroplating solution may comprise one or more additives, such as the first additive 121, second additive 122, and/or third additive 123 described in greater detail below. The first additive 121, the second additive 122, and the third additive 123 may be collectively referred to herein as the additives 120. The use of the additives 121, 122 and 123 as described herein can result in the deposition of a copper layer comprising mostly (111)-oriented grains, as described previously. In some embodiments, the first additive 121 acts as a relatively weak suppressor (e.g. a relatively weak suppressing agent) that suppresses the growth of Cu²⁺ that is not (111)-oriented and/or promotes the growth of Cu²⁺ that is (111)-oriented. In some embodiments, the second additive 122 acts as a relatively strong suppressor (e.g. a relatively strong suppressing agent) that suppresses the growth of Cu²⁺ on sidewall surfaces. In some embodiments, the third additive 123 acts as a leveler (e.g., a leveling agent) that suppresses the growth of Cu²⁺ on raised surfaces, thus promoting overall surface planarity. In some embodiments, the additives 120 and/or the electroplating solution are free of accelerating additives (e.g., accelerating agents).

The additives 120 may be added together to the electroplating solution prior to performing the electroplating process, or the additives 120 may be added to the electroplating solution in different stages or steps during the electroplating process. In this manner, the absolute or relative concentrations of the first additive 121, the second additive 122, and the third additive 123 within the electroplating solution may change throughout the electroplating process. As an example, the second additive 122 may be initially added to the electroplating solution prior to performing the electroplating process, and then the first additive 121 and the third additive 123 may be subsequently added to the electroplating solution during the electroplating process. In some cases, adding the second additive 122 first can better suppress the growth of Cu²⁺ on sidewalls during the electroplating process. This is an example, and the additives 120 may be added to the electroplating solution in a different manner in other embodiments.

In some embodiments, the first additive 121 comprises a molecule having at least one suppressing functional group and at least one metal-coordinating functional group. The suppressing functional group(s) of the first additive 121 may suppress growth of non-(111)-oriented Cu²⁺ during the electroplating process. In some embodiments, a suppressing functional group of the first additive 121 may comprise a hydrogen functional group, an aliphatic functional group, an aromatic functional group, a combination thereof, or the like. In some embodiments, a suppressing functional group of the first additive 121 may comprise a hydroxyl functional group, an ether functional group, an amine functional group, a sulfide functional group, a carboxylic acid functional group, an ester functional group, an amide functional group, an imide functional group, an imine functional group, a combination thereof, or the like. Other suppressing functional groups are possible. A molecule of the first additive 121 may comprise multiple suppressing functional groups, which may be similar or different.

The metal-coordinating functional group of the first additive may promote (111)-oriented growth of Cu²⁺, and may facilitate non-(111)-oriented Cu²⁺ becoming (111)-oriented. In some embodiments, a metal-coordinating functional group of the first additive 121 may comprise a hydroxyl functional group, an ether functional group, an amine functional group, a sulfide functional group, a carboxylic acid functional group, an ester functional group, an amide functional group, an imide functional group, an imine functional group, a combination thereof, or the like. Other metal-coordinating functional groups are possible. A molecule of the first additive 121 may comprise multiple metal-coordinating functional groups, which may be similar or different. In some cases, a Fourier transform infrared (FTIR) spectroscopy analysis may be able to determine the type or composition of a metal-coordinating functional group of the first additive 121.

In some embodiments, the first additive 121 may comprise gelatin or the like. In some embodiments, the first additive 121 may comprise the following structure:

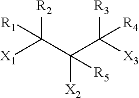

In this example structure, R₁, R₂, R₃, R₄, and R₅ represent suppressing functional groups, which may be similar or different, and X₁, X₂, and X₃ represent metal-coordinating functional groups, which may be similar or different. The suppressing functional groups R₁, R₂, R₃, R₄ and/or R₅ may be similar to the suppressing functional groups described above, and the metal-coordinating functional groups X₁, X₂, and/or X₃ may be similar to the metal-coordinating functional groups described above. However, as one of ordinary skill in the art will recognize, the above presented example is intended to be illustrative only and is not intended to limit the scope.

The combination of suppressing functional group(s) and metal-coordinating functional group(s) on the first additive 121 can encourage the formation of (111)-oriented copper and suppress the formation of non-(111)-oriented copper. In some embodiments, the first additive 121 does not suppress growth of Cu²⁺ as much as the second additive 122 (described below). Thus, the first additive 121 may be considered a relatively weak suppressor, in some cases. In some embodiments, the first additive 121 has an average molecular weight greater than about 5000 Da, such as a molecular weight in the range of about 5000 Da to about 20000 Da, though other molecular weights are possible. In some embodiments, the first additive 121 has an average molecular weight that is less than that of the second additive 122. For example, in some embodiments, the average molecular weight of the first additive 121 may be about the same as or less than about half of the average molecular weight of the second additive 122. Molecules of the first additive 121 may be smaller than molecules of the second additive 122, in some embodiments. The molar concentration of the first additive 121 in the electroplating solution may be in the range of about 0.05 mol/L to about 50 mol/L, but other concentrations are possible.

In some embodiments, the second additive 122 comprises relatively large molecules that accumulate on sidewalls and some other surfaces and suppress the growth of Cu²⁺ on those surfaces. For example, the second additive 122 may suppress the growth of Cu²⁺ on sidewalls of the opening 118 and on top surfaces of the dielectric layer 114. In some cases, the presence of the second additive 122 on sidewalls of the opening 118 can form copper having a less concave surface within the opening 118. In some embodiments, the second additive 122 is polymeric and comprises macromolecules having linear structures, branched structures, cross-linked structures, or a combination thereof. In some embodiments, the second additive 122 comprises organic molecules, including but not limited to polymer and organic frameworks. In some embodiments, the second additive 122 comprises a polyether compound. In some embodiments, the second additive 122 comprises polyalkylene oxide random copolymers including as polymerized units two or more alkylene oxide monomers or ethylene oxide-propylene oxide random copolymers. In some embodiments, the second additive 122 is derived from polyethylene oxide (PEO), polypropylene oxide (PPO), polyethylene glycol (PEG), polypropylene glycol (PPG), or their derivatives or co-polymers. Other second additives 122 are possible.

In some cases, the second additive 122 may suppress growth of Cu²⁺ more than the first additive 121. Thus, the second additive 122 may be considered a relatively strong suppressor, in some cases. In some embodiments, the second additive 122 has an average molecular weight greater than about 10000 Da, such as a molecular weight in the range of about 10000 Da to about 100000 Da, though other molecular weights are possible. In some embodiments, the second additive 122 comprises repeating units, and each unit has a molecular weight greater than about 50 Da. In some embodiments, the second additive 122 has an average molecular weight that is greater than that of the first additive 121. For example, in some embodiments, the average molecular weight of the second additive 122 may be about the same as or greater than about twice the average molecular weight of the first additive 121. Molecules of the second additive 122 may be larger than molecules of the first additive 121, in some embodiments. The molar concentration of the second additive 122 in the electroplating solution may be in the range of about 0.01 mol/L to about 10 mol/L, but other concentrations are possible.

In some embodiments, the third additive 123 comprises molecules that locally suppress the growth of Cu²⁺ on protrusions, edges, and the like, which can increase the planarity of the deposited copper during the electroplating process. In this manner, the third additive 123 may be considered a leveler or a leveling agent. In some embodiments, the third additive 123 may comprise organic molecules, nitrogen-containing molecules, sulfur-containing molecules, or the like. In some embodiments, the molecules of the third additive 123 are positively charged in the electroplating solution. In some embodiments, the third additive 123 comprises one or more nitrogen, amine, imide, imidazole or pyrrolidone groups, and may also comprise sulfur functional groups. In some embodiments, the leveler additive comprises one or more five-member rings, six-member rings, and/or conjugated organic compound derivatives. In some embodiments, nitrogen groups may form part of the ring structure. In some embodiments, in a third additive 123 comprising one or more amines, the amines are primary, secondary or tertiary alkyl amines. In some embodiments, the amine is an aryl amine or a heterocyclic amine. In some embodiments, the amines include, but are not limited to, dialkylamines, trialkylamines, arylalkylamines, triazoles, imidazole, triazole, tetrazole, benzimidazole, benzotriazole, piperidine, morpholines, piperazine, pyridine, pyrrolidone, oxazole, benzoxazole, pyrimidine, quonoline, isoquinoline, the like, or a combination thereof. In some embodiments, the third additive 123 comprises polyvinylpyrrolidone (PVP). In some embodiments, the third additive 123 comprises Janus Green B, Nitroblue tetazolium (NBT), or the like. In some embodiments, the third additive 123 may be a molecule comprising positively-changed nitrogen. In some cases, a nuclear magnetic resonance (NMR) analysis may be able to determine that the third additive 123 is a molecule comprising positively-charged nitrogen. Other third additives 123 are possible.

In some embodiments, the third additive 123 has an average molecular weight in the range of about 500 Da to about 30000 Da, though other molecular weights are possible. The third additive 123 may have an average molecular weight that is greater than, less than, or about the same as the average molecular weight of the first additive 121. In some embodiments, the third additive 123 has an average molecular weight that about the same as or less than about twice the average molecular weight of the first additive 121. The molar concentration of the third additive 123 in the electroplating solution may be in the range of about 0.01 mol/L to about 10 mol/L, but other concentrations are possible.

FIGS. 5-9 illustrate intermediate stages in the formation of copper 130 using an electroplating process, in accordance with some embodiments. The electroplating process may be similar to that described above. For example, FIGS. 5-9 may represent the structure of FIG. 4 when submerged in an electroplating solution during an electroplating process. The electroplating solution comprises additives 120 (e.g., additives 121, 122, 123), which may be similar to those described above. In the figures, the first additive 121 is represented by a rounded rectangle shape, the second additive 122 is represented by an elongated hexagonal shape, and the third additive is represented by a triangle shape. FIGS. 5-9 are intended as representative illustrations for explanatory purposes, and accordingly some features are not shown for clarity reasons. For example, some portions of the structure underlying the dielectric layer 114 are not shown in FIGS. 5-9 and components of the electroplating solution other than the additives 120 are not shown in FIGS. 5-9. Further, the additives 121, 122, and 123 shown in the figures are representative, and may be present in other locations than illustrated.

Turning to FIG. 5, copper 130 is deposited in lower portions of the opening 118, in accordance with some embodiments. As shown in FIG. 5, in some cases, the first additive 121 may tend accumulate near lower portions of the opening 118, and the second additive 122 may tend to accumulate on sidewalls of the opening 118 and on top surfaces of the dielectric layer 114. In some cases, the smaller size of the first additive 121 allows it to diffuse and accumulate more easily on lower portions of the opening 118 than the larger second additive 122. Additionally, because the first additive 121 is a weaker suppressor than the second additive 122, the growth rate of copper 130 near bottom surfaces of the opening 118 is greater than the growth rate of copper 130 on sidewalls of the opening 118 and on top surfaces of the dielectric layer 114. In this manner, the copper 130 is formed from the bottom of the opening 118 upward to fill the opening 118. Forming the copper 130 with a bottom-up process can decrease the risk of voids or cracks forming in the conductive feature 112. The third additive 123 may promote planar bottom-up growth of the copper 130.

Due to the effects of the first additive 121 described above, the copper 130 includes nanotwinned regions 132 that are substantially (111)-oriented. In some embodiments, the central portions of the copper 130 within the opening 118 are nanotwinned regions 132, and the portions of the copper 130 near the sidewalls of the opening 118 are transition regions 134. The nanotwinned regions 132 are regions that mostly comprise (111)-oriented grains of copper. The transition regions 134 are regions that have a smaller proportion of (111)-oriented grains of copper, due to the sidewall surfaces affecting the growth of copper. In some cases, the transition regions 134 may be formed due to subconformal deposition on the sidewalls of the opening 118. In some embodiments, at least about 97% (by volume) of the nanotwinned regions 132 is (111)-oriented copper, with the rest of the copper having other orientations. However, in the transition regions 134, the proportion of (111)-oriented copper may be as low as about 40% (by volume). The proportion of non-uniform grains in the transition regions 134 may be greater than the proportion of non-uniform grains in the nanotwinned regions 132. In other words, the density of (111)-oriented grains in the nanotwinned regions 132 is greater than the density of (111)-oriented grains in the transition regions 134. In some embodiments, the crystalline grains in the nanotwinned regions 132 have larger average dimensions than the crystalline grains in the transition regions 134. In some embodiments, a width WB of a transition region 134 may be between about 0% and about 30% of a width WA of a nanotwinned region 132. In some cases, the width WB may be a distance between an edge of a nanotwinned region 132 and a sidewall of the opening 118. The width WB may or may not include the seed layer 116.

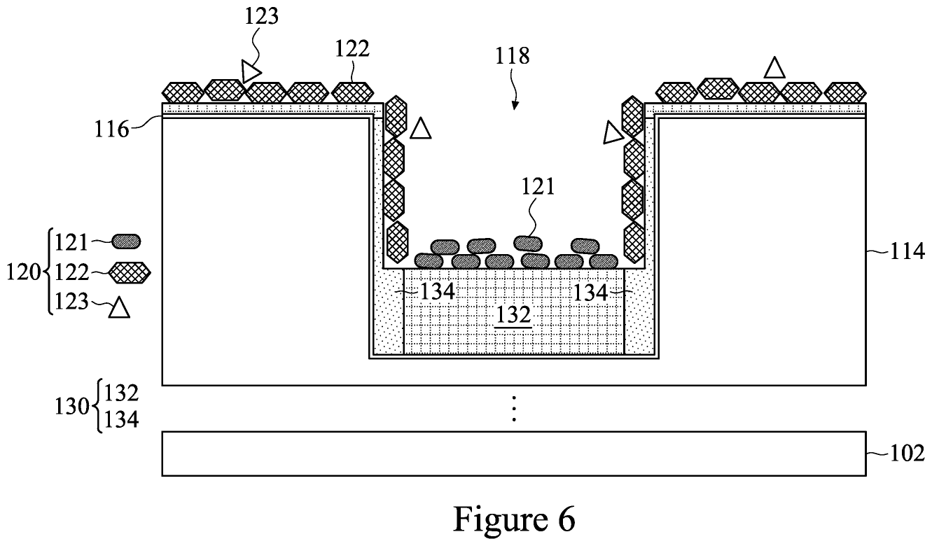

FIG. 6 shows a subsequent intermediate stage in the formation of copper 130, in accordance with some embodiments. As shown in FIG. 6, as the copper 130 is deposited bottom-up, copper 130 may also be deposited on sidewalls of the opening 118 and on top surfaces of the dielectric layer 114. The growth rate of copper 130 on sidewalls of the opening 118 and on top surfaces of the dielectric layer 114 may be relatively slow. In some embodiments, the copper 130 may be deposited on the sidewalls of the opening 118 as transition regions 134, and the copper 130 may be deposited on top surfaces of the dielectric layer 114 as nanotwinned regions 132. In some cases, the copper 130 may be deposited on top surfaces of the dielectric layer as transition regions 134.

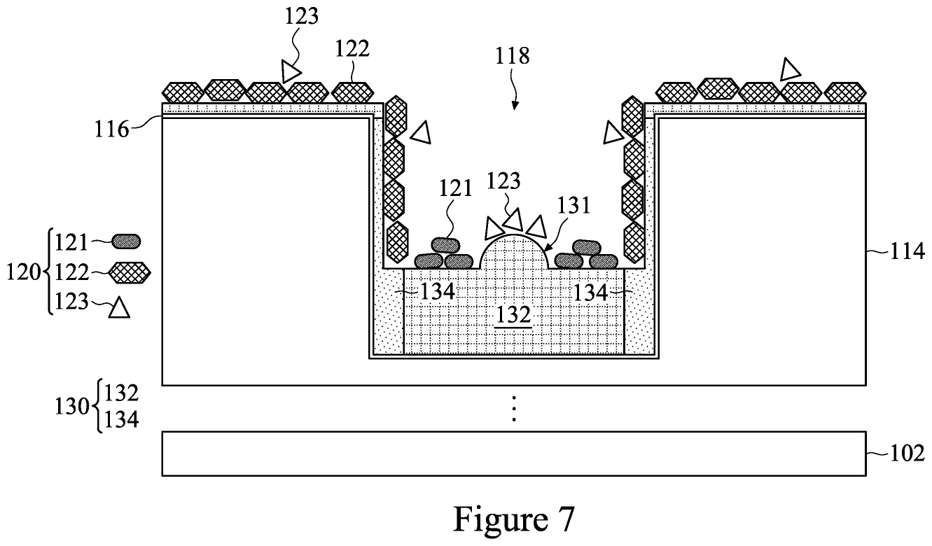

In some cases, the surface of the copper 130 within the opening 118 may have an approximately convex shape, in which central regions may be higher than regions near the sidewalls. An example is illustrated in FIG. 7, in which the top surface of a central nanotwinned region 132 has a protrusion 131 that is higher than the top surfaces of the outer transition regions 134. In such cases, the third additive 123 may accumulate near the protrusion 131 and retard growth in the region around the protrusion 131. In this manner, the third additive 123 may smooth out protrusions and irregularities and form more level surfaces of copper 130.

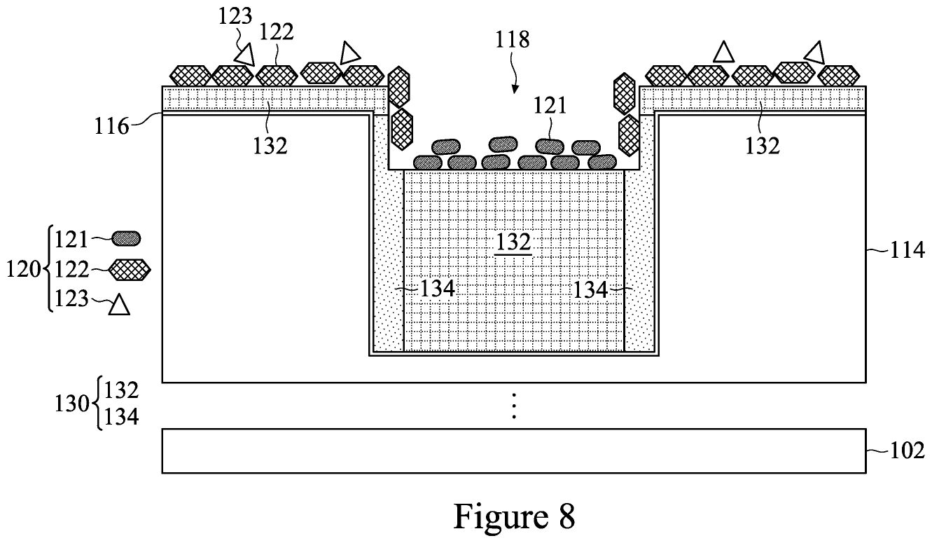

FIG. 8 illustrates a subsequent intermediate stage in the formation of copper 130, in accordance with some embodiments. As shown in FIG. 8, additional copper 130 may form on the sidewalls of the opening 118 and/or the top surfaces of the dielectric layer 114, but top surfaces of the copper 130 within the opening 118 grows at a faster rate. In this manner, the bottom-up formation of copper 130 within the opening 118 continues.

FIG. 9 illustrates a subsequent intermediate stage in the formation of copper 130, in accordance with some embodiments. In FIG. 9, the electroplating process has continued until the copper 130 fills the opening 118, in accordance with some embodiments. In this manner, a conductive feature 112 may be formed of electroplated copper 130 that includes nanotwinned regions 132. In some embodiments, an upper portion 113A of the conductive feature 112 extending over the dielectric layer 114 may be a conductive line or the like, and a lower portion 113B of the conductive feature 112 within the opening 118 may be a conductive via or the like. This is an example, and different portions of the conductive feature 112 may be other types of features in other cases. As shown in FIG. 9, in some embodiments, the volume of the conductive feature 112 may mostly comprise nanotwinned regions 132. The non-nanotwinned regions, such as transition regions 132, form a smaller proportion of the conductive feature 112 than the nanotwinned regions 132. In some embodiments, the upper portion 113A over the dielectric layer 114 may mostly comprise nanotwinned regions 132. Transition regions 134 may be present near sidewalls of the opening 118 (e.g., near sidewalls of the lower portion 113B). Transition regions 134 may be present in other locations, in some cases.

In some embodiments, the width WA of a nanotwinned region 132 of the portion 113B may be in the range of about 0.5 μm to about 40 μm. Due to the presence of the transition regions 134, the width WA may be less than a width W1 (see FIG. 3) of the opening 118. In some embodiments, a width WB of a transition region 134 is less than a width WA of a nanotwinned region 132. A width WB of a transition region 134 may be in the range of about 0 μm to about 12 m. In some embodiments, a height HA of the copper 130 on top surfaces of the dielectric layer 114 (e.g., a height HA of the upper portion 112A) may be in the range of about 0.5 μm to about 10 μm. In some embodiments, a height HB of a transition region 134 may be less than a depth D1 (see FIG. 3) of the opening 118. In some embodiments, a width W2 of the upper portion 113A may be in the range of about 0.5 μm to about 50 μm. In some cases, the width W2 of a conductive feature 112 may be greater than a width W1 of an opening 118. These are examples, and other absolute or relative dimensions for WA, WB, W2, HA, and/or HB are possible.

As described previously, the presence of the third additive 123 in the electroplating solution can improve planarity during an electroplating process and thus can improve planarity of the conductive feature 112. For example, in some cases, the techniques described herein can form a conductive feature 112 having a top surface with a roughness Ra that is about 20 μm or less. In this manner, conductive features 112 having substantially smooth and planar surfaces may be formed.

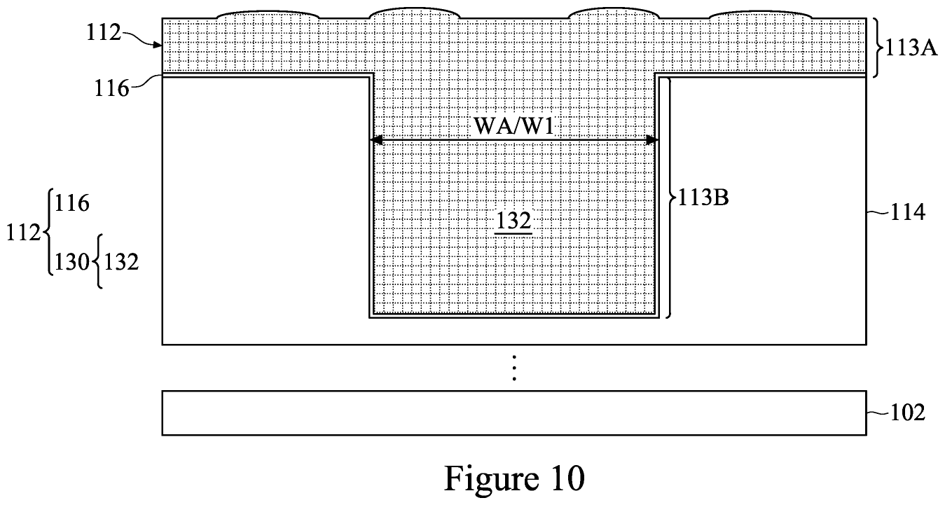

In some embodiments, the copper 130 deposited during the electroplating process comprises little or no transition regions 134. Accordingly, FIG. 10 illustrates a conductive feature 112 that only comprises nanotwinned regions 132 of copper 130. In other words, the conductive feature 112 of FIG. 10 comprises at least about 97% (by volume) of (111)-oriented copper 130. Both the upper portion 113A and the lower portion 113B may be nanotwinned regions 132. In such embodiments, the width WA of a nanotwinned region 132 in the lower portion 113B may be about same as the width W1 of the opening 118. In some cases, one or more transition regions 134 may be present in the conductive feature 112 but be of an insignificant size. In some cases, the surface roughness Ra of the conductive feature 112 of FIG. 10 may be less than about 20 m.

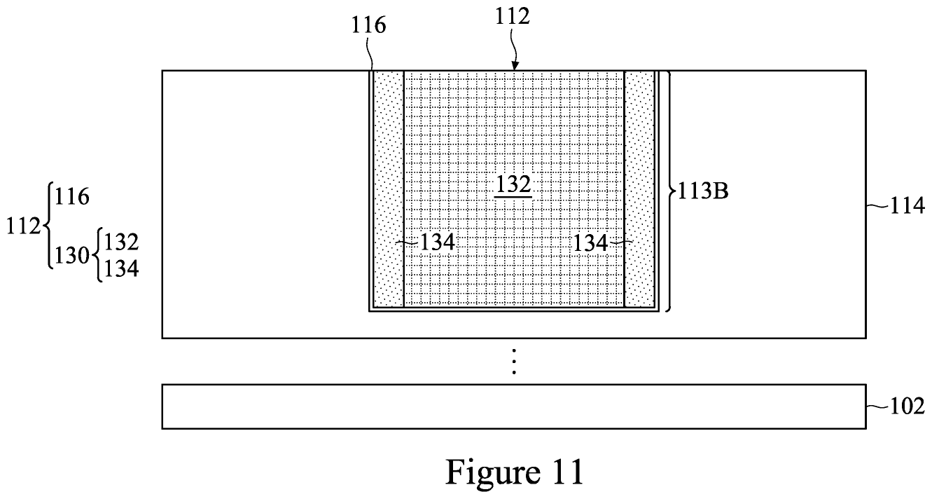

In some embodiments, a planarization process may be performed to remove the upper portion 113A such that the final conductive feature 112 only comprises the lower portion 113B. For example, the planarization process may comprise a chemical mechanical polish (CMP) process, a grinding process, an etching process, or a combination thereof. In some embodiments, the planarization process may also remove upper portions of the dielectric layer 114. In some cases, after performing the planarization process, top surfaces of the dielectric layer 114 and the copper 130 may be substantially level or coplanar. The planarization process may expose the transition regions 134, as shown in FIG. 11. In other embodiments, nanotwinned regions 132 may cover the transition regions 134 such that top surfaces of the transition regions 134 are not exposed by the planarization process. In some cases, the conductive feature 112 may be formed using a damascene process, and the planarization process may be performed as part of the damascene process. The damascene process may be a single damascene process, a dual damascene process, or the like.

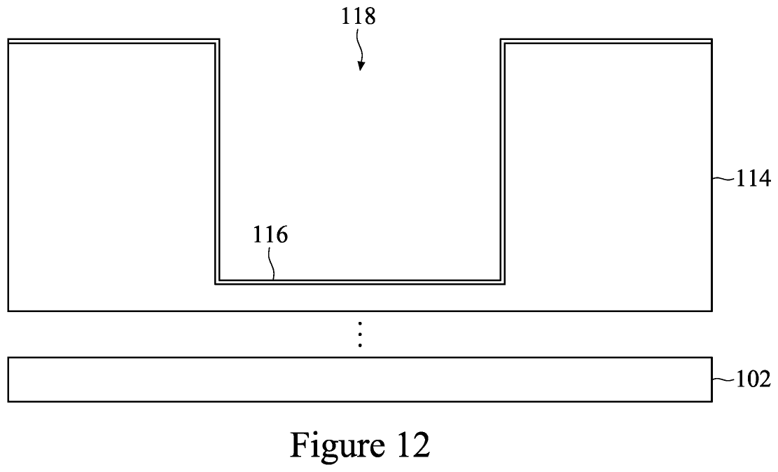

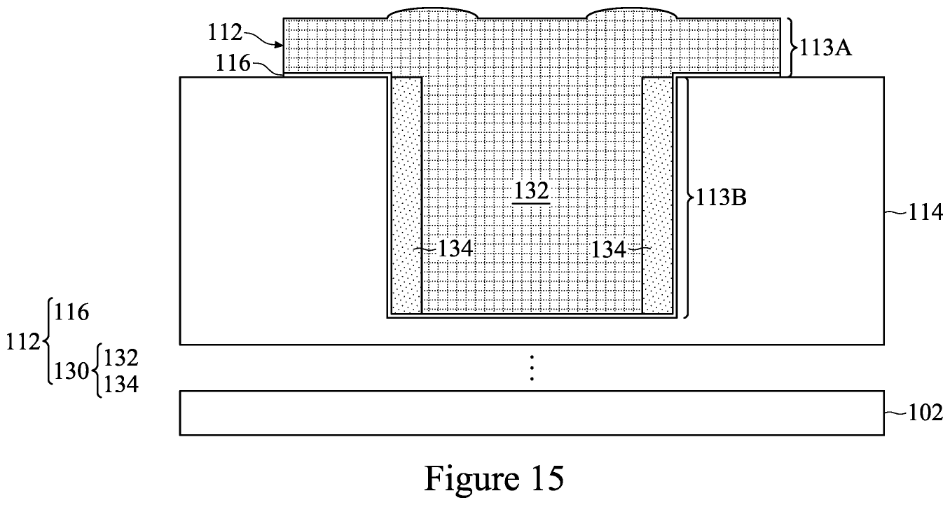

FIG. 12 through 15 illustrates intermediate stages in the formation of a conductive feature 112 (see FIG. 15), in accordance with some embodiments. The conductive feature 112 of FIG. 15 may be similar to the conductive feature 112 of FIG. 9, and formed using some similar processes. For example, the conductive feature 112 of FIG. 15 may be formed of copper 130 deposited using an electroplating process similar to that described for FIGS. 5-9. The conductive feature 112 of FIG. 15 may be formed in a dielectric layer 114, and may be part of an interconnect structure 110 or the like. In some cases, the conductive feature 112 of FIG. 15 may be considered a redistribution layer.

FIG. 12 illustrates a structure similar to that of FIG. 4, in accordance with some embodiments. For example, FIG. 12 illustrates a dielectric layer 114 comprising an opening 118 and a seed layer 116 that has been deposited over the dielectric layer 114 and within the opening 118. The dielectric layer 114, opening 118, and seed layer 116 may be similar to those of FIG. 4 and may be formed using similar materials or techniques.

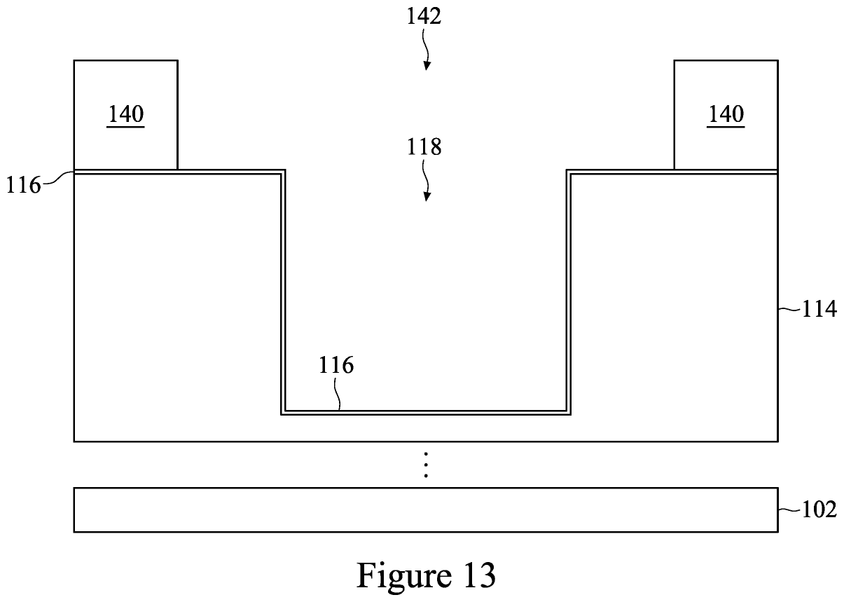

In FIG. 13, a photoresist 140 is formed and patterned on the seed layer 116, in accordance with some embodiments. The photoresist 140 may be patterned using suitable photolithography and etching techniques. For example, the photoresist 140 may be formed by spin coating or the like and may be exposed to light for patterning. The pattern of the photoresist 140 corresponds to the subsequently formed conductive feature 112. The photoresist 140 may then be developed to form openings 142 through the photoresist 140 to expose the seed layer 116. In the embodiment shown in FIG. 13, the opening 118 in the dielectric layer 114 is within an opening 142 in the photoresist 140.

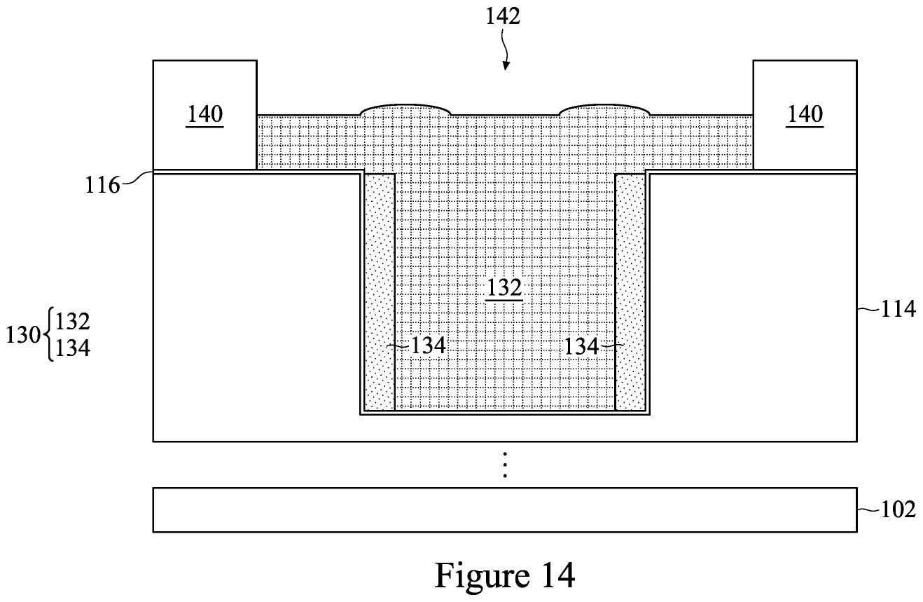

In FIG. 14, copper 130 is deposited in the opening 142 using an electroplating process, in accordance with some embodiments. The electroplating process forms copper 130 on exposed surfaces of the seed layer 116. The electroplating process may be similar to that described previously for FIGS. 5-9. For example, the electroplating process may utilize an electroplating solution that comprises additives 120, which may include first additive 121, second additive 122, and/or third additive 123. Accordingly, the copper 130 may largely be formed of nanotwinned regions 132, and may also include transition regions 134 near sidewalls of the opening 118. In this manner, a conductive feature 112 may be formed of copper 130 that is mostly (111)-oriented.

In FIG. 15, the photoresist 140 and portions of the seed layer 116 are removed to form the conductive feature 112. Then, the photoresist 140 and portions of the seed layer 116 on which the copper 130 is not formed are removed. The photoresist 140 may be removed by an acceptable ashing or stripping process, such as using an oxygen plasma or the like. Once the photoresist 140 is removed, exposed portions of the seed layer 116 are removed using, for example, a suitable wet etching process and/or a suitable dry etching process. The remaining portions of the seed layer 116 and copper 130 form the conductive feature 112. This is an example, and other techniques for forming a conductive feature 112 using the electroplating process described herein are possible.

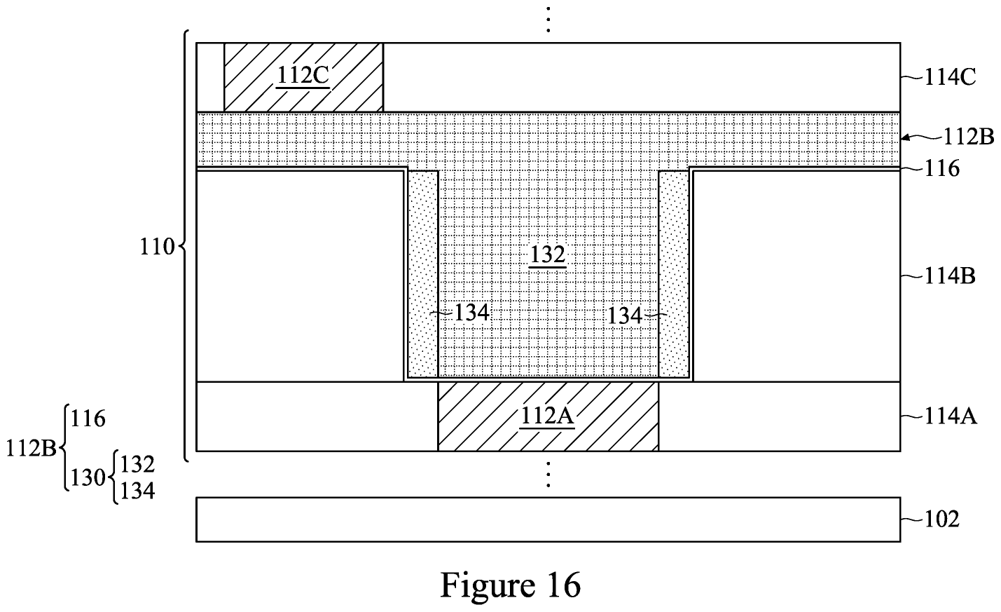

FIG. 16 illustrates a portion of an interconnect structure 110 over a substrate 102, in accordance with some embodiments. The interconnect structure 110 may be similar to the interconnect structure 110 described previously for FIG. 1. For example, the interconnect structure 110 may include a plurality of conductive features 112 formed in a plurality of dielectric layers 114. FIG. 16 illustrates three conductive features 112A-C formed in three dielectric layers 114A-C, but an interconnect structure 110 may include any suitable number of conductive features 112 or dielectric layers 114. The conductive features 112A-C may be similar to the conductive features 112 described previously, and may be formed using an electroplating process such as those described previously. For example, the conductive features 112A-C may mostly comprise (111)-oriented copper. The dielectric layers 114A-C may be similar to the dielectric layers 114 described previously. In some cases, other layers such as etch stop layers may be present in an interconnect structure 110.

FIG. 16 illustrates a conductive feature 112B that is physically and electrically connected to an underlying conductive feature 112A and an overlying conductive feature 112C. For example, the conductive feature 112A may first be formed in a dielectric layer 114A using techniques similar to those described above. In some cases, the conductive feature 112A may be a contact (e.g., contact 108 of FIG. 1) or the like.

The conductive feature 112B may then be formed over the conductive feature 112A using techniques similar to those described above. For example, the dielectric layer 114B may be deposited over the conductive feature 112A and the dielectric 114A. The dielectric layer 114B may then be patterned using suitable photolithography and etching techniques to form an opening that exposes the underlying conductive feature 112A. A seed layer 116 may be deposited over the dielectric layer 114B and on the conductive feature 112A, in some embodiments. An electroplating process may then be performed to deposit copper 130 over the dielectric layer 114B and the conductive feature 112A, forming the conductive feature 112B. The conductive feature 112B may comprise nanotwinned regions 132 and transition regions 134. A dielectric layer 114C may then be deposited over the conductive feature 112B and the dielectric layer 114B. A conductive feature 112C may then be formed extending through the dielectric layer 114C to contact the conductive feature 112B. Processes described above may be repeated to form any number of additional conductive features or dielectric layers. This is an example, and other processes for forming an interconnect structure 110 are possible.

Embodiments may achieve advantages. By electroplating copper using additives in the electroplating solution as described herein, conductive features may be formed that mostly comprise regions of (111)-oriented copper, which may be nanotwinned regions of (111)-oriented copper. In some cases, these regions may be 97% or more (111)-oriented copper. By forming conductive features that are mostly (111)-oriented copper, the conductive features may have benefits of (111)-oriented copper such as improved mechanical and thermal properties. In some cases, the embodiments described herein can form conductive features having smooth, planar surfaces, such as surfaces with a roughness less than 20 μm. This can allow for the formation of conductive features with a reduced risk of forming voids or other defects, and can form conductive features having planar surfaces without the use of polishing processes. In some embodiments, the electroplating solution comprises a weak suppressor additive that includes a suppressing functional group and a metal-coordinating functional group, a strong suppressor additive, and a leveler additive.

In accordance with some embodiments of the present disclosure, a method includes adding a first additive to an electroplating solution, wherein the first additive is a relatively weak suppressing agent; adding a second additive to the electroplating solution, wherein the second additive is a relatively strong suppressing agent; adding a third additive to the electroplating solution, wherein the third additive is a leveling agent; and depositing copper using the electroplating solution, wherein most of the copper is nanotwinned grains having a (111)-orientation. In an embodiment, the electroplating solution includes a copper salt, a source of halide ions, and an acid. In an embodiment, the first additive is gelatin. In an embodiment, the first additive includes a suppressing functional group and a metal-coordinating functional group. In an embodiment, the second additive includes a polymer having an average molecular weight that is greater than 10,000 Da. In an embodiment, an average molecular weight of the first additive is less than half of an average molecular weight of the second additive. In an embodiment, the nanotwinned grains having a (111)-orientation form at least 97% of the copper by volume. In an embodiment, the first additive and the second additive are added to the electroplating solution after the second additive is added to the electroplating solution.

In accordance with some embodiments of the present disclosure, a method includes forming an opening in a dielectric layer; depositing copper in the opening using an electroplating process, wherein the copper deposited in the opening is (111)-oriented, wherein the electroplating process includes using an electroplating solution, wherein the electroplating solution includes: a first additive, wherein the first additive includes a suppressing functional group and a metal-coordinating functional group; and a second additive, wherein the second additive is polymeric. In an embodiment, the copper deposited in the opening includes a first copper region surrounded by a second copper region, wherein the first copper region has a greater proportion of (111)-oriented copper than the second region. In an embodiment, the suppressing functional group includes a hydrogen functional group, an aliphatic functional group, or an aromatic functional group. In an embodiment, the metal-coordinating functional group includes a hydroxyl functional group, an ether functional group, an amine functional group, a sulfide functional group, a carboxylic acid functional group, an ester functional group, an amide functional group, an imide functional group, or an imine functional group. In an embodiment, the second additive has a linear or branched structure. In an embodiment, the electroplating solution includes a third additive, wherein the third additive includes positively-charged nitrogen.

In accordance with some embodiments of the present disclosure, a device includes a dielectric layer over a substrate; and a conductive via in the dielectric layer, wherein the conductive via includes a first nanotwinned copper region and a second nanotwinned copper region, wherein the first nanotwinned copper region is separated from a sidewall of the dielectric layer by the second nanotwinned copper region, wherein the first nanotwinned copper region has a greater density of (11)-oriented grains than the second nanotwinned copper region. In an embodiment, at least 97% of the grains in the first nanotwinned copper region are (111)-oriented, and at least 40% of the grains in the second nanotwinned copper region are (111)-oriented. In an embodiment, the device includes a conductive line on top surfaces of the conductive via and the dielectric layer, wherein at least 97% of the grains in the conductive line are (111)-oriented. In an embodiment, a top surface of the conductive line has a roughness that is less than 20 m. In an embodiment, an average grain size of the first nanotwinned copper region is greater than an average grain size of the second nanotwinned copper region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
adding a first additive to an electroplating solution, wherein the first additive is a relatively weak suppressing agent;
adding a second additive to the electroplating solution, wherein the second additive is a relatively strong suppressing agent;
adding a third additive to the electroplating solution, wherein the third additive is a leveling agent; and
depositing copper using the electroplating solution, wherein most of the copper comprises nanotwinned grains having a (111)-orientation.

2. The method of claim 1, wherein the electroplating solution further comprises a copper salt, a source of halide ions, and an acid.

3. The method of claim 1, wherein the first additive is gelatin.

4. The method of claim 1, wherein the first additive comprises a suppressing functional group and a metal-coordinating functional group.

5. The method of claim 1, wherein the second additive comprises a polymer having an average molecular weight that is greater than 10,000 Da.

6. The method of claim 1, wherein an average molecular weight of the first additive is less than half of an average molecular weight of the second additive.

7. The method of claim 1, wherein the nanotwinned grains having a (111)-orientation comprise at least 97% of the copper by volume.

8. The method of claim 1, wherein the first additive and the second additive are added to the electroplating solution after the second additive is added to the electroplating solution.

9. A method comprising:
forming an opening in a dielectric layer;
depositing copper in the opening using an electroplating process, wherein the copper deposited in the opening is (111)-oriented, wherein the electroplating process comprises using an electroplating solution, wherein the electroplating solution comprises:
a first additive, wherein the first additive comprises a suppressing functional group and a metal-coordinating functional group; and
a second additive, wherein the second additive is polymeric.

10. The method of claim 9, wherein the copper deposited in the opening comprises a first copper region surrounded by a second copper region, wherein the first copper region has a greater proportion of (111)-oriented copper than the second region.

11. The method of claim 9, wherein the suppressing functional group comprises a hydrogen functional group, an aliphatic functional group, or an aromatic functional group.

12. The method of claim 9, wherein the metal-coordinating functional group comprises a hydroxyl functional group, an ether functional group, an amine functional group, a sulfide functional group, a carboxylic acid functional group, an ester functional group, an amide functional group, an imide functional group, or an imine functional group.

13. The method of claim 9, wherein the first additive has the following structure: 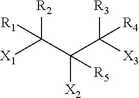
wherein R₁, R₂, R₃, R₄, and R₅ are suppressing functional groups, and wherein X₁, X₂, and X₃ are metal-coordinating functional groups.

14. The method of claim 9, wherein the second additive has a linear or branched structure.

15. The method of claim 9, wherein the electroplating solution further comprises a third additive, wherein the third additive comprises positively-charged nitrogen.

16. A device comprising:
a dielectric layer over a substrate; and
a conductive via in the dielectric layer, wherein the conductive via comprises a first nanotwinned copper region and a second nanotwinned copper region, wherein the first nanotwinned copper region is separated from a sidewall of the dielectric layer by the second nanotwinned copper region, wherein the first nanotwinned copper region has a greater density of (111)-oriented grains than the second nanotwinned copper region.

17. The device of claim 16, wherein at least 97% of the grains in the first nanotwinned copper region are (111)-oriented, and wherein at least 40% of the grains in the second nanotwinned copper region are (111)-oriented.

18. The device of claim 16 further comprising a conductive line on top surfaces of the conductive via and the dielectric layer, wherein at least 97% of the grains in the conductive line are (111)-oriented.

19. The device of claim 18, wherein a top surface of the conductive line has a roughness that is less than 20 m.

20. The device of claim 16, wherein an average grain size of the first nanotwinned copper region is greater than an average grain size of the second nanotwinned copper region.
